(19) United States
(12) Patent Application Publication
(10) Pub. No.: US 2010/0213848 A1
(43) Pub. Date: Aug. 26, 2010

(54) DETECT METHOD FOR STEP DIMMING SELECTION

(75) Inventors: Wei Gao, Guangzhou (CN); Markus Heckmann, Muenchen (DE); Rene Twardzik, Traunreut (DE); Yanshun Xue, Guangzhou (CN)

Correspondence Address: Viering, Jentschura & Partner - OSR, 3770 Highland Ave., Suite 203, Manhattan Beach, CA, 90266, US

(73) Assignee: OSRAM GESELLSCHAFT MIT BESCHRAENKTER HAFTUNG, Muenchen (DE)

(21) Appl. No.: 12/667,047

(22) PCT Filed: Jun. 12, 2008
(86) PCT No.: PCT/EP2008/057377

§ 371 Date: Apr. 15, 2010

(30) Foreign Application Priority Data
Jun. 29, 2007 (CN) 200710126327.3

(51) Int. Cl. H05B 41/298; G01R 31/24

(52) U.S. Cl. 315/86; 324/414

(57) ABSTRACT

A detect method is provided for performing step dimming selection in an electronic ballast including an End of Lamp Life detect circuit and a half-bridge inverter, the End of Lamp Life detect circuit being connected to an input terminal of the control circuit, wherein each time when the power switch is turned on, it is judged whether the electronic ballast should enter the dimming mode or not by detecting the voltage at the input terminal of the control circuit before the half-bridge inverter starts operating.

### TECHNICAL FIELD

The invention relates to a new detect method for step dimming selection in an electronic ballast. The detect method provides enough information to the control IC to judge whether dimming mode should be active or not using the End of Lamp Life (EOLL) detect circuit.

### BACKGROUND OF THE INVENTION

As is well-known, when the life of a fluorescent lamp comes to an end, the ballast makes the lamp work continuously, thus causing over-heat of the lamp and generating discharge “smog”, meanwhile, a very high voltage is generated at the cathode of the lamp to put the lamp and the ballast in an abnormal and dangerous state. Therefore, the End of Lamp Life detect circuit is more and more widely used in the electronic ballast controlled by an Application Specific Integrated Circuit (ASIC) or a Microcontroller.

Meanwhile, reducing the output power of the high-performance electronic ballast when full output is unnecessary can not only functions to save energy and prolong the lifetime of the lamp, but also change the visual effect. Thus it is particularly meaningful to integrate a dimming selection function in the electronic ballast in this time when energy saving is gaining more and more attention.

However, in order to simultaneously achieve the above two functions in the electronic ballast, by use of the existing known circuits, there is no other choice but to integrate the two kinds of protection circuits at the same time, this not only increases the cost, but also requires complicated circuits that include a lot of elements and components.

### SUMMARY OF THE INVENTION

It is, therefore, a technical problem to be solved by the present invention to achieve the functions of End of Lamp Life protection and dimming selection simultaneously in an electronic ballast in a cheap, simple and reliable way.

To solve this technical problem, the basic concept of the technical solution adopted by the invention is that it is judged whether the electronic ballast should enter the dimming mode or not by detecting the voltage at the input terminal of the control circuit of the electronic ballast.

In an electronic ballast comprising a half-bridge inverter and End of Lamp Life detect circuit, the End of Lamp Life detect circuit is connected to an input terminal of the control circuit, each time when the power switch is turned on, it is judged whether the electronic ballast should enter the dimming mode or not by detecting the voltage at the input terminal of the control circuit before the half-bridge inverter starts operating.

According to one aspect of the invention, if the voltage detected at the input terminal of the control circuit before the half-bridge inverter starts operating is higher than a comparison threshold value, the dimming mode should be active.

According to another aspect of the invention, the comparison threshold value is preferably equal to the comparison threshold value of the End of Lamp Life detect circuit. Theoretically, the comparison threshold value can be any threshold value below the stable voltage under normal operation and above zero. The comparison threshold value can be chosen to be between +25V and −25V.

According to still another aspect of the invention, the End of Lamp Life detect circuit is a mean value filter for detecting the asymmetrical voltages across the fluorescent lamp.

According to yet another aspect of the invention, the control circuit can be an Application Specific Integrated Circuit or a Microcontroller.

The detect method of the present invention can also be used for emergency lighting system. Analogously, when there is a power interruption and a power recovery by the back-up power source, the electronic ballast is caused to make a correct response by detecting the voltage at the input of the control circuit before the half-bridge inverter starts operating.

The advantages of the detect method of the present invention are as follows:

1. Only one power switch is needed to control the electronic ballast on/off and full output mode/dimming mode.

2. The detect method does not add any additional component to realize a new function.

3. No additional pin is requested to realize this dimming mode selection function because it is combined with EOLL detect pin if a control ASIC is used to control the ballast.

4. No additional input port is requested to realize this dimming mode selection function because it is combined with EOLL detect input port if a Microcontroller is used to control the ballast.

5. No additional control switch or hardware is requested to give some information to the control circuit, but the primary power switch which is necessary for all ballast.

### BRIEF DESCRIPTION OF THE DRAWINGS

The invention will be better appreciated by the descriptions of the embodiments with reference to the figures, wherein:

FIG. 1 shows a typical circuit for fluorescent lamp ballast including a half-bridge inverter and EOLL detect circuit.

FIG. 2 shows a typical circuit within the control Integrated Circuit.

### DETAILED DESCRIPTION

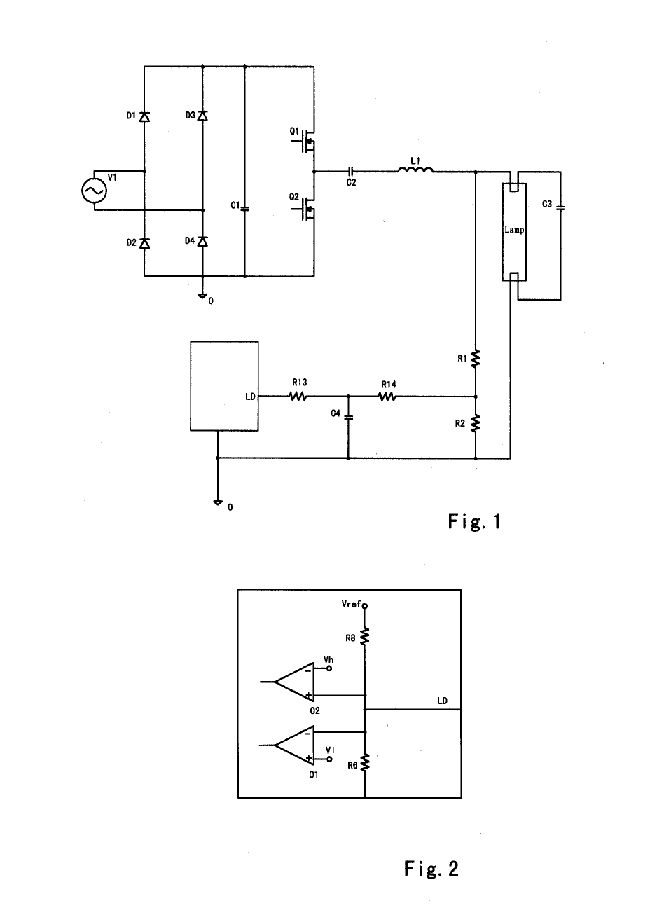

FIG. 1 shows a typical circuit for fluorescent lamp ballast including a half-bridge inverter and EOLL detect circuit.

In FIG. 1, resistors R1, R2, R14 and capacitor C4 form an EOLL detect circuit that is a mean value filter detecting the asymmetrical voltage across the fluorescent lamp and connecting to an input terminal LD of the control circuit (for example an ASIC). The typical circuit of the part of the control is show in FIG. 2. To achieve the function of EOLL detection, the voltage levels of the input terminal LD of the control circuit and capacitor C4 are very similar during operation of the control circuit, and this can be realized by optimizing the parameters of the components. In the text below, voltage of the input terminal LD of the control circuit always means the voltage of the input terminal LD and the voltage of capacitor C4.

During normal operation, the voltage level of the input terminal LD is close to ½ Vref. When the power supply to the ballast is cut by turning off the power switch, the ballast would stop running and no voltage is given by reference voltage Vref. Then the voltage level of the input terminal LD would drop and the time constant is a function of the capacitance of the capacitor C4 and the resistance of resistors R1, R2, R6 and R8.

It shall be noted that the OFF TIME is the time interval of the power switch from being turned off to being turned on, and said OFF TIME is associated with the voltage level of the input terminal LD of the control circuit before the half-bridge inverter starts operating. Besides, the OFF TIME can show the desire of the user in making the ballast enter full power mode or dimming mode. Therefore, each time the power switch is turned on, the control circuit should detect the voltage level of the input terminal LD before the half-bridge inverter starts operating to get the information about the OFF TIME.

The control circuit can recognize the OFF TIME by detecting the voltage level of the input terminal LD before the half-bridge inverter starts operating to judge if the ballast should enter the dimming mode or not. For example, if the voltage on LD is higher than a comparison threshold value, dimming mode should be active and vice verse. Preferably, the comparison threshold value can be equal to the comparison threshold value of the EOLL detect circuit so as to save cost. Theoretically, the comparison threshold value can be any threshold value below the stable voltage under normal operation and above zero. But appropriate values will be specified in view of cost and application. If the range of the comparison threshold value should be specified, it should be between +25V and −25V.

In addition, the detect method of the invention can not only be used for step dimming, but also for emergency lighting system.

In the safety rules of some European countries, special requirements are set for the ballast used in emergency lighting system. That is, at a time of power interruption and recovery of power by back-up power supply, the light source should emit light within 0.5 second. The detect method of the present invention can detect this process of quick recovery after power interruption, thereby making the internal control circuit to respond correctly.

While the invention has been described in conjunction with specific embodiments, it is evident that many alternatives, modifications and variations will be apparent to those skilled in the art in light of the foregoing description. Accordingly, it is intended to embrace all such alternatives, modifications and variations as fall within the spirit and scope of the appended claims.

1. A detect method for performing step dimming selection in an electronic ballast including an End of Lamp Life detect circuit and a half-bridge inverter, the End of Lamp Life detect circuit being connected to an input terminal of the control circuit, wherein each time when the power switch is turned on, it is judged whether the electronic ballast should enter the dimming mode or not by detecting the voltage at the input terminal of the control circuit before the half-bridge inverter starts operating.

2. The detect method according to claim 1, wherein if the voltage detected at the input terminal of the control circuit is higher than a comparison threshold value, the dimming mode should be active.

3. The detect method according to claim 2, wherein the comparison threshold value is equal to the comparison threshold value of the End of Lamp Life detect circuit.

4. The detect method according to claim 2, wherein the comparison threshold value can be any threshold value below the stable voltage under normal operation and above zero.

5. The detect method according to claim 2, wherein the comparison threshold value is chosen to be between +25V and −25V.

6. The detect method according to claim 1, wherein the End of Lamp Life detect circuit is a mean value filter for detecting the asymmetrical voltages across the fluorescent lamp.

7. The detect method according to claim 1, wherein the control circuit is an Application Specific Integrated Circuit or a Microcontroller.

8. A detect method for use in an emergency light system, which an electronic ballast including an End of Lamp Life detect circuit and a half-bridge inverter contains, the End of Lamp Life detect circuit being connected to an input terminal of the control circuit, wherein at the time of power interruption and power recovery by back-up power supply, the control circuit is made to respond correctly by detecting the voltage at the input terminal of the control circuit before the half-bridge inverter starts operating.
